(19) United States
(12) Patent Application Publication
(10) Pub. No.: US 2026/0275514 A1
(43) Pub. Date: Sep. 17, 2026

(54) SEMICONDUCTOR MANUFACTURING DEVICE

(71) Applicant: Kioxia Corporation, Tokyo (JP)

(72) Inventor: Naoto ASAKURA, Yokkaichi Mie (JP)

(73) Assignee: Kioxia Corporation, Tokyo (JP)

(21) Appl. No.: 19/328,553

(22) Filed: Sep. 15, 2025

(30) Foreign Application Priority Data
Mar. 14, 2025 (JP) 2025-041006

(51) Int. Cl. C23C 16/44

(52) U.S. Cl. CPC C23C 16/4412

(57) ABSTRACT

A semiconductor manufacturing device capable of suppressing backflow of unrequired products contained in exhaust gas is provided. According to one embodiment, the semiconductor manufacturing device includes a pipe through which exhaust gas from a process chamber flows in a first direction, and a plurality of traps provided on an inner peripheral surface of the pipe at intervals in the first direction. Each of the plurality of traps includes a recessed portion provided on the inner peripheral surface and recessed from the inner peripheral surface toward an outer side of the pipe, and a shielding surface that extends from an edge of the recessed portion into the pipe along a second direction intersecting the first direction.

### CROSS-REFERENCE TO RELATED APPLICATION

This application is based upon and claims the benefit of priority from Japanese Patent Application No. 2025-041006, filed Mar. 14, 2025, the entire contents of which are incorporated herein by reference.

### FIELD

Embodiments described herein relate generally to a semiconductor manufacturing device.

### BACKGROUND

A semiconductor device such as a three-dimensional memory may be manufactured by performing film formation processing using a semiconductor manufacturing device such as a CVD device.

### BRIEF DESCRIPTION OF THE DRAWINGS

FIG. 1 is a schematic diagram illustrating a configuration example of a semiconductor manufacturing device.

FIG. 2 is a graph illustrating an example of pressure fluctuation during film formation processing.

FIG. 3 is a schematic diagram illustrating an internal structure of a pipe 30.

FIG. 4 is a schematic diagram illustrating a structure example of a pipe unit for forming a pipe in a first embodiment.

FIG. 5 is a schematic diagram illustrating the structure example of the pipe unit for forming the pipe in the first embodiment.

FIG. 6 is a schematic diagram illustrating a structure example of the pipe in the first embodiment.

FIG. 7 is a schematic diagram illustrating the structure example of the pipe in the first embodiment.

FIG. 8 is a schematic diagram illustrating another structure example of the pipe in the first embodiment.

FIG. 9 is a schematic diagram illustrating another structure example of the pipe in the first embodiment.

FIG. 10 is a schematic diagram illustrating a structure example of a pipe in a second embodiment.

FIG. 11 is a schematic diagram illustrating the structure example of the pipe in the second embodiment.

FIG. 12 is a schematic diagram illustrating a structure example of a pipe unit for forming a pipe in a third embodiment.

FIG. 13 is a schematic diagram illustrating the structure example of the pipe unit for forming the pipe in the third embodiment.

FIG. 14 is a schematic diagram illustrating a structure example of a pipe in a fourth embodiment.

FIG. 15 is a schematic diagram illustrating a structure example of a pipe unit for forming a pipe in the fourth embodiment.

FIG. 16 is a schematic diagram illustrating the structure example of the pipe unit for forming the pipe in the fourth embodiment.

FIG. 17 is a schematic diagram illustrating a structure example of a pipe unit for forming a pipe in a fifth embodiment.

FIG. 18 is a schematic diagram illustrating the structure example of the pipe unit for forming the pipe in the fifth embodiment.

FIG. 19 is a schematic diagram illustrating a structure example of a pipe in a sixth embodiment.

FIG. 20 is a schematic diagram illustrating a structure example of a pipe unit for forming a pipe in a seventh embodiment.

FIG. 21 is a schematic diagram illustrating a structure example of a pipe unit for forming a pipe in an eighth embodiment.

### DETAILED DESCRIPTION

One problem to be solved is to provide a semiconductor manufacturing device capable of suppressing a backflow of unrequired products included in exhaust gas.

In general, according one embodiment, a semiconductor manufacturing device of embodiments includes a pipe through which exhaust gas from a process chamber flows in a first direction, and a plurality of traps provided on an inner peripheral surface of the pipe at intervals in the first direction. Each of the plurality of traps includes a recessed portion provided on the inner peripheral surface and recessed from the inner peripheral surface toward an outer side of the pipe, and a shielding surface that extends from an edge of the recessed portion into the pipe along a second direction intersecting the first direction.

Hereinafter, embodiments will be described with reference to the drawings. A relationship between a thickness and a plane dimension of each component illustrated in the drawings, a ratio of the thickness of each component, and the like may differ from actual ones. Further, in the embodiments, substantially same components are denoted by same reference signs, and description thereof is appropriately omitted.

### Semiconductor Manufacturing Device

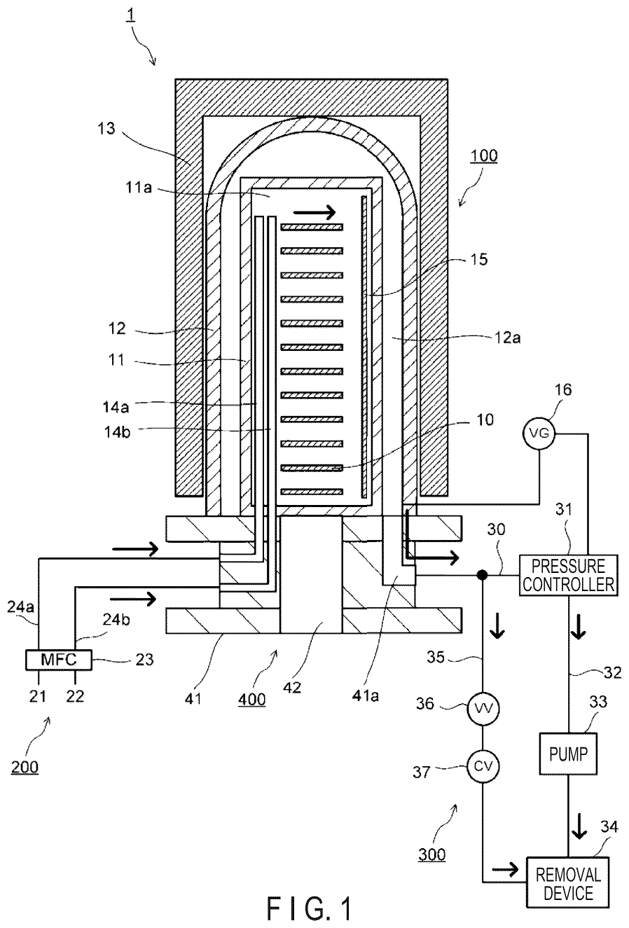

FIG. 1 is a schematic diagram illustrating a configuration example of the semiconductor manufacturing device. FIG. 1 illustrates a configuration example of a vertical type LP-CVD (Low Pressure Chemical Vapor Deposition: LP-CVD) device 1. In an implementation, the semiconductor manufacturing device may be the LP-CVD device, or may be other CVD devices such as an atomic layer deposition (ALD) device.

The LP-CVD device 1 includes a processing unit 100, a supply unit 200 for supplying gas to the processing unit 100, an exhaust unit 300 for discharging the gas from the processing unit 100, and a conveyance unit 400 for carrying an object 10 in and out of the processing unit 100. FIG. 1 further illustrates a flow of the gas indicated by arrows.

The processing unit 100 includes an inner pipe 11, an outer pipe 12, an outer wall 13, a nozzle 14a, a nozzle 14b, a thermometer 15, and a manometer 16.

The inner pipe 11 has a space 11a where the object 10 can be disposed. The space 11a forms a process chamber for processing the object 10. Processing of the object 10 includes film formation processing of introducing raw material gas and forming a film on a surface of the object 10, for example. The object 10 is held by a holding member called a boat that is disposed in the space 11a, for example. The object 10 is a semiconductor substrate processed by LP-CVD. The object 10 may be a plurality of semiconductor substrates. Examples of the semiconductor substrate include a semiconductor wafer on which a semiconductor device is formed or a semiconductor device is under formation. Examples of the semiconductor wafer include a silicon wafer.

The outer pipe 12 is disposed on an outer side of the inner pipe 11. The outer pipe 12 is provided so as to surround the inner pipe 11, and has a space 12a between the inner pipe 11 and itself.

The outer wall 13 is provided on an outer side of the outer pipe 12. The outer wall 13 may be provided so as to surround the outer pipe 12.

The nozzle 14a can supply first gas to the space 11a. The first gas contains silicon atoms. Examples of the first gas include silane (SiH₄) or the like. The nozzle 14a may have a plurality of discharge ports from which the first gas is discharged for example.

The nozzle 14b can supply second gas to the space 11a. The second gas contains oxygen atoms. Examples of the second gas include oxygen (O₂) or the like. The nozzle 14b may have a plurality of discharge ports from which the second gas is discharged for example.

The thermometer 15 is disposed inside the space 11a for example. The thermometer 15 can measure a temperature of the space 11a for example. The temperature of the space 11a can be adjusted by a heater for example.

The manometer 16 can measure a pressure of an exhaust route including the space 12a and a pipe 30. The manometer 16 is connected to the space 12a for example. The manometer 16 may be disposed inside the space 12a.

The supply unit 200 includes a gas supply source 21, a gas supply source 22, a flow rate adjuster 23, a pipe 24a, and a pipe 24b.

The gas supply source 21 can supply the first gas. Examples of the gas supply source 21 include a cylinder cabinet or the like.

The gas supply source 22 can supply the second gas. Examples of the gas supply source 22 include a cylinder cabinet or the like.

The flow rate adjuster 23 includes a plurality of mass flow controllers. A flow rate of the first gas and a flow rate of the second gas can be adjusted by the corresponding mass flow controllers. Thus, supply and stop of the first gas and supply and stop of the second gas can be switched for example.

The exhaust unit 300 includes the pipe 30, a pressure controller 31, a pipe 32, a pump 33, a removal device 34, a pipe 35, a vent valve 36, and a check valve 37.

Through the pipe 30, exhaust gas discharged from the processing unit 100 flows. The pipe 30 is connected to the space 12a via a space 41a for example.

The pressure controller 31 can control a pressure of the exhaust route. The pressure controller 31 is connected to the pipe 30. The pressure controller 31 may include a pressure adjusting valve for example. The pressure controller 31 is connected to the manometer 16, and may control the pressure of the exhaust route including the pipe 30 according to the pressure measured by the manometer 16 for example. In addition, the manometer 16 and the pressure controller 31 are connected to an unillustrated controller, and may control the pressure of the exhaust route including the pipe 30 according to the pressure measured by the manometer 16 using the controller.

Through the pipe 32, the exhaust gas from the pressure controller 31 flows. The pipe 32 is connected to the pressure controller 31 and is connected to the pipe 30 via the pressure controller 31.

The pump 33 is provided in the middle of the pipe 32. The pump 33 can supply the exhaust gas to the removal device 34.

The removal device 34 can process the exhaust gas and remove toxic substances in the exhaust gas. The processed exhaust gas is discharged into the atmosphere for example.

The pipe 35 is branched from the pipe 30 and is connected to the removal device 34. In an implementation, the pipe 35 may be directly connected to a pipe for atmosphere discharge for example without being connected to the removal device 34.

The vent valve 36 is provided in the middle of the pipe 35. The vent valve 36 is opened as needed for example to discharge the exhaust gas and adjust the pressure of the pipe 30. Thus, when the pressure of the pipe 30 exceeds a desired value for example, by discharging the exhaust gas from the pipe 35, the pressure of the pipe 30 can be lowered.

The check valve 37 is provided in the middle of the pipe 35 in a subsequent stage of the vent valve 36. The check valve 37 can prevent a backflow of the exhaust gas for example.

The conveyance unit 400 is disposed on a lower side of the inner pipe 11. The conveyance unit 400 has a conveyance mechanism 42 surrounded by a heat insulator 41 for example. The conveyance mechanism 42 can carry the object 10 in and out of the processing unit 100. Between the heat insulator 41 and the conveyance mechanism 42, a space 41a is provided. The space 41a is connected to the space 12a.

When performing the film formation processing of a silicon oxide film or the like for example using the LP-CVD device 1, the first gas and the second gas are alternately supplied for example, fluctuation of the pressure becomes large and the back flow is likely to occur.

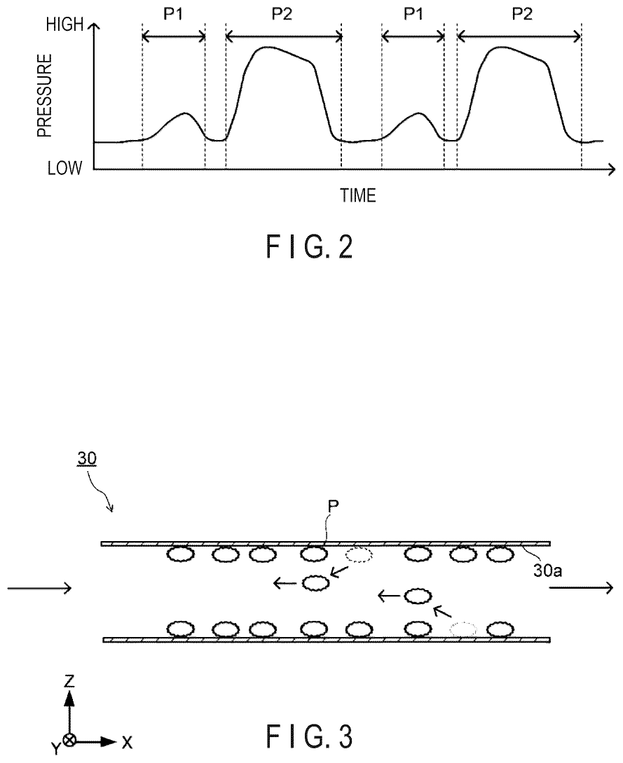

FIG. 2 is a graph illustrating an example of the fluctuation of the pressure during the film formation processing. A horizontal axis in FIG. 2 indicates time, and a vertical axis indicates the pressure measured by the manometer 16.

As illustrated in FIG. 2, when alternately switching a period P1 of supplying the first gas and a period P2 of supplying the second gas to perform the film formation processing, the pressure greatly fluctuates at the time of switching between the period P1 and the period P2.

FIG. 3 is a schematic diagram illustrating an internal structure of the pipe 30. FIG. 3 schematically illustrates a cross-sectional structure example of the pipe 30 along an exhaust gas flow direction (an X axis direction for example). FIG. 3 indicates an X axis, a Y axis, and a Z axis. They perpendicularly intersect each other. When performing the film formation processing, as illustrated in FIG. 3, unrequired products P stick to an inner peripheral surface 301a of the pipe 30. Examples of the products P include silicon oxide or the like. When the backflow occurs, some of the products P move to the processing unit 100, causing generation of particles and performance decline of the LP-CVD device 1.

Therefore, the semiconductor manufacturing device of the embodiments includes a trap for suppressing the backflow of the products P. A specific structure example of the trap will be described below.

### First Embodiment

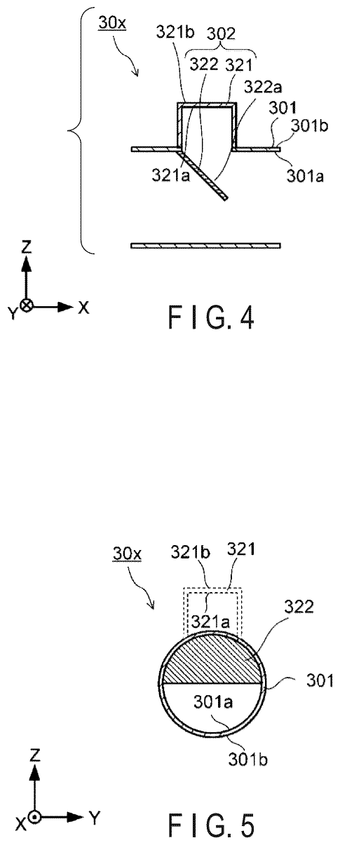

FIG. 4 and FIG. 5 are schematic diagrams illustrating a structure example of a pipe unit for forming the pipe 30 of the first embodiment. FIG. 4 schematically illustrates a cross-sectional structure example of a pipe unit 30x along the exhaust gas flow direction (the X axis direction for example). FIG. 5 schematically illustrates a structure example of the pipe unit 30x when viewed from a direction (a Z axis direction for example) perpendicular to the exhaust gas flow direction. FIG. 4 and FIG. 5 indicate the X axis, the Y axis, and the Z axis.

The pipe unit 30x includes a pipe 301 and a trap 302.

The pipe 301 includes the inner peripheral surface 301a and an outer peripheral surface 301b.

The trap 302 is provided on the inner peripheral surface 301a. The trap 302 includes a recessed portion 321 and a shielding body 322.

The recessed portion 321 is provided on the inner peripheral surface 301a. The recessed portion 321 is recessed from the inner peripheral surface 301a to an outer side of the pipe 301. In other words, the recessed portion 321 is projected from the outer peripheral surface 301b to the outer side of the pipe 301. In an implementation, the recessed portion 321 may have a prism shape such as a quadrangular prism or a columnar shape for example. The recessed portion 321 may be joined with the pipe 301 by welding. In an implementation, an interior of the recessed portion 321 is in fluid communication with an interior of the pipe 301.

The shielding body 322 can suppress movement of the products P in a direction opposite to the exhaust gas flow direction. The shielding body 322 extends from an edge of the recessed portion 321 into the pipe 301 along a direction intersecting the X axis direction without blocking the pipe 30. In an implementation, as illustrated in FIG. 4, an angle formed by an extending direction of the shielding body 322 and a length direction of the pipe unit 30 x is 45 degrees, or the shielding body 322 and the pipe unit 30x may form an angle other than 45 degrees. In an implementation, the shielding body 322 extends from a part closer to an exit side of the pipe unit 30x than an entrance side at the edge of the recessed portion 321. In an implementation, the shielding body 322 extends from a part or edge of the recessed portion 321 that is closer to an entrance side of the pipe unit 30x than an exit side at the edge of the recessed portion 321. The shielding body 322 has a shielding surface 322a on a side of the recessed portion 321. The shielding body 322 can be formed using a metal material for example, and is formed using stainless steel such as SUS for example. The shielding body 322 may be joined with the inner peripheral surface 301a by welding. The shielding surface 322a may have a function of capturing the products P.

The shielding surface 322a has a semicircular shape along the inner peripheral surface 301a for example. The semicircular shape may extend so as to overlap a center axis of the pipe 301 in a first direction.

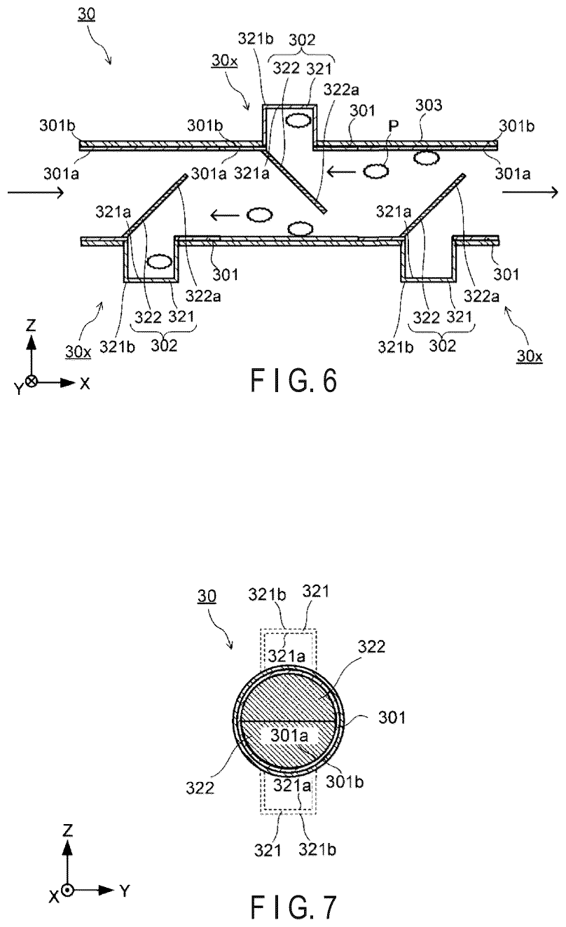

FIG. 6 and FIG. 7 are schematic diagrams illustrating a structure example of the pipe 30 in the first embodiment. FIG. 6 schematically illustrates a cross-sectional structure example of the pipe unit 30x along the exhaust gas flow direction (the X axis direction for example). FIG. 7 schematically illustrates the structure example of the pipe unit 30x when viewed from the direction (the Z axis direction for example) perpendicular to the exhaust gas flow direction.

The pipe 30 is formed by combining the plurality of pipe units 30x along one direction (the X axis direction for example). In an implementation, as illustrated in FIG. 6 and FIG. 7, the three pipe units 30x are combined, or the number of the pipe units 30x may be another number.

The plurality of traps 302 are disposed at intervals in the X axis direction for example.

The plurality of pipes 301 are joined by welding for example. In an implementation, the plurality of pipes 301 may be connected by being fitted with each other for example.

One of the plurality of recessed portions 321 is recessed to or at an upper side of the pipe 30 along the Z axis direction. Another one of the plurality of recessed portions 321 is recessed to or at a lower side of the pipe 30 along the Z axis direction. One of the plurality of recessed portions 321 and another one of the plurality of recessed portions 321 may be alternately disposed (e.g., at the lower and upper sides) along the X axis direction.

The plurality of shielding surfaces 322a are disposed so as to at least partially overlap each other in the X axis direction, however, in an implementation, they may be disposed so as not to overlap each other in the X axis direction.

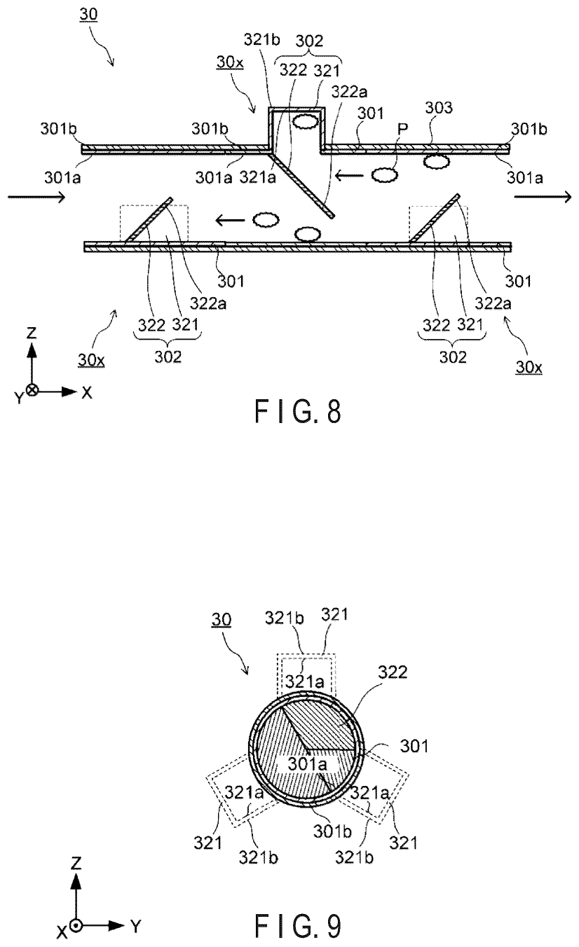

FIG. 8 and FIG. 9 are schematic diagrams illustrating another structure example of the pipe 30 in the first embodiment. FIG. 8 schematically illustrates a cross-sectional structure example of the pipe unit 30x along the exhaust gas flow direction (the X axis direction for example) indicated by arrows. FIG. 9 schematically illustrates the structure example of the pipe unit 30x when viewed from the direction (the Z axis direction for example) perpendicular to the exhaust gas flow direction. Hereinafter, parts different from FIG. 6 and FIG. 7 will be described and description of FIG. 6 and FIG. 7 can be appropriately referred to for the other parts.

The pipe 30 illustrated in FIG. 8 and FIG. 9 is different in that the plurality of recessed portions 321 are recessed to or at the outer side of the pipe 30 in directions different from each other. While an angle formed by extending directions of the adjacent recessed portions 321 is 120 degrees for example.

The LP-CVD device 1 may include a heater 303 surrounding the outer peripheral surfaces 301b of the plurality of pipes 301. The heater 303 is provided in contact with the outer peripheral surface 301b of the pipe 301. The heater 303 can heat the pipe 30. In an implementation, a heating temperature may be between 170° C. and 190° C. for example. At least a part of an outer surface 321b of the recessed portion 321 is exposed from, by, or through the heater 303. In other words, at least a part of the outer surface 321b of the recessed portion 321 is not in contact with or covered by the heater 303. Thus, a temperature of the recessed portion 321 can be made lower than a temperature of the pipe 30, and the products P are cooled by the recessed portion 321 and are easily captured by the trap 302.

As described above, the pipe 30 in the present embodiment includes the trap 302 provided with the recessed portion 321 and the shielding body 322, the movement of the products P can be obstructed by the shielding body 322, and the products P can be made to stay in the recessed portion 321, so that the backflow of the products P can be suppressed. Thus, reliability of the semiconductor manufacturing device can be improved.

The first embodiment can be appropriately combined with the other embodiments.

### Second Embodiment

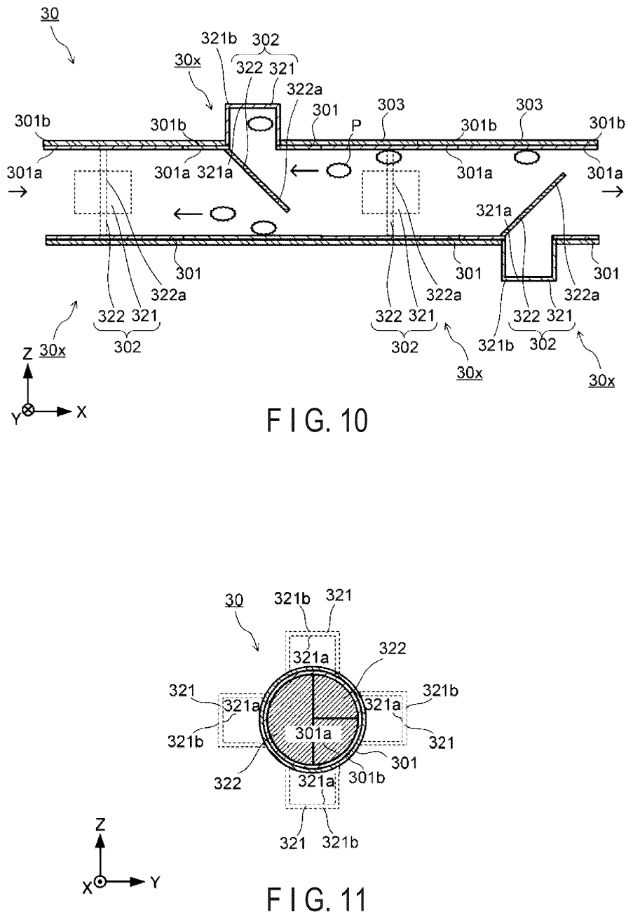

FIG. 10 and FIG. 11 are schematic diagrams illustrating a structure example of the pipe 30 in the second embodiment. FIG. 10 schematically illustrates a cross-sectional structure example of the pipe unit 30x along the exhaust gas flow direction (the X axis direction for example) indicated by arrows. FIG. 11 schematically illustrates the structure example of the pipe unit 30x when viewed from the direction (the Z axis direction for example) perpendicular to the exhaust gas flow direction. Hereinafter, parts different from FIG. 6 and FIG. 7 will be described and the description of FIG. 6 and FIG. 7 can be appropriately referred to for the other parts.

The pipe 30 illustrated in FIG. 10 and FIG. 11 is different in that it is formed by combining four pipe units 30x. While the angle formed by the extending directions of the adjacent recessed portions 321 is 90 degrees for example. In an implementation, the number of the pipe units 30x may be a number other than four.

One of the plurality of recessed portions 321 is recessed to or at the upper side of the pipe 30 along the Z axis direction. Another one of the plurality of recessed portions 321 is recessed to or at a left side of the pipe 30 along the Z axis direction. Another one of the plurality of recessed portions 321 is recessed to or at the lower side of the pipe 30 along the Z axis direction. The other one of the plurality of recessed portions 321 is recessed to or at a right side of the pipe 30 along the Z axis direction. These four recessed portions 321 may be repeatedly disposed in order along the X axis direction.

The second embodiment can be appropriately combined with the other embodiments.

### Third Embodiment

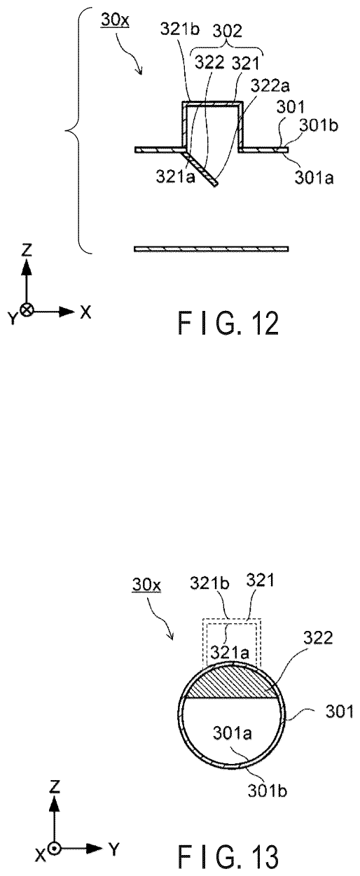

FIG. 12 and FIG. 13 are schematic diagrams illustrating a structure example of the pipe unit for forming the pipe 30 in the third embodiment. FIG. 12 schematically illustrates a cross-sectional structure example of the pipe unit 30x along the exhaust gas flow direction (the X axis direction for example). FIG. 13 schematically illustrates the structure example of the pipe unit 30x when viewed from the direction (the Z axis direction for example) perpendicular to the exhaust gas flow direction. Hereinafter, parts different from FIG. 4 and FIG. 5 will be described and the description of FIG. 4 and FIG. 5 can be appropriately referred to for the other parts.

The pipe unit 30x illustrated in FIG. 12 and FIG. 13 is different in that the shielding surface 322a of the shielding body 322 is not semicircular but has a bow shape along the inner peripheral surface 301a. A bowstring of the bow shape is disposed so as not to overlap a center axis in the X axis direction of the pipe 301 for example. Thus, obstruction of the flow of the exhaust gas can be suppressed.

The third embodiment can be appropriately combined with the other embodiments. For example, similarly to the other embodiments, the pipe 30 can be formed by combining the plurality of pipe units 30x illustrated in FIG. 12 and FIG. 13.

### Fourth Embodiment

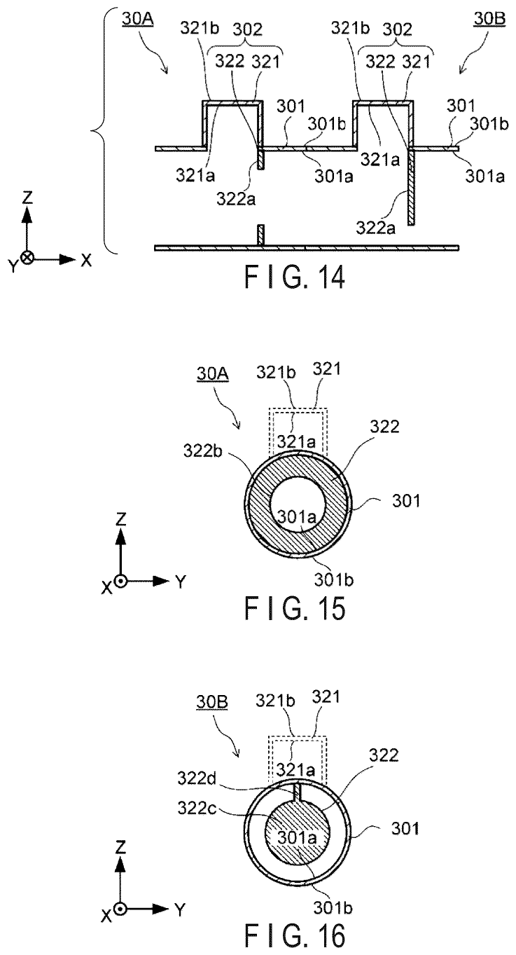

FIG. 14 is a schematic diagram illustrating a structure example of the pipe 30 in the fourth embodiment. FIG. 14 schematically illustrates a cross-sectional structure example of the pipe along the exhaust gas flow direction (the X axis direction for example). FIG. 15 is a schematic diagram illustrating a structure example of a pipe unit 30A forming the pipe 30 in the fourth embodiment. FIG. 15 schematically illustrates the structure example of the pipe unit 30A when viewed from the direction (the Z axis direction for example) perpendicular to the exhaust gas flow direction. FIG. 16 is a schematic diagram illustrating a structure example of a pipe unit 30B forming the pipe 30 in the fourth embodiment. FIG. 16 schematically illustrates the structure example of the pipe unit 30B when viewed from the direction (the Z axis direction for example) perpendicular to the exhaust gas flow direction. Hereinafter, parts different from FIG. 4 and FIG. 5 will be described and the description of FIG. 4 and FIG. 5 can be appropriately referred to for the other parts.

The pipe 30 illustrated in FIG. 14 is different in that it is formed by combining the pipe unit 30A and the pipe unit 30B. The pipe unit 30A and the pipe unit 30B may be alternately disposed along the X axis direction.

The plurality of pipes 301 are joined by welding for example. In an implementation, the plurality of pipes 301 may be connected by being fitted with each other for example.

The shielding surface 322a in the pipe unit 30a is, as illustrated in FIG. 15, an annular surface provided with an opening 322b. The annular surface extends (e.g., inwardly) from the edge of the recessed portion 321 into the pipe 301 along the Z axis direction for example. The description of the pipe unit 30x can be appropriately referred to for the other description of the pipe unit 30A.

The shielding surface 322a in the pipe unit 30B includes, as illustrated in FIG. 16, a circular surface 322c and a beam surface 322d that connects the circular surface 322c and the inner peripheral surface 301a. The circular surface 322c overlaps a part or all of the opening 322b in the X axis direction of the pipe 30 for example. The circular surface 322c extends from the edge of the recessed portion 321 into the pipe 301 along the Z axis direction for example. A width of the beam surface 322d may be smaller than a diameter of the circular surface 322c. The description of the pipe unit 30x can be appropriately referred to for the other description of the pipe unit 30B.

As described above, the pipe 30 in the fourth embodiment can suppress the backflow of the products P by combining the pipe unit 30A and the pipe unit 30B provided with the plurality of shielding surfaces 322a in different shapes.

The fourth embodiment can be appropriately combined with the other embodiments. For example, similarly to the other embodiments, the pipe 30 can be formed by combining the plurality of pipe units 30A and 30B illustrated in FIG. 14, FIG. 15, and FIG. 16.

### Fifth Embodiment

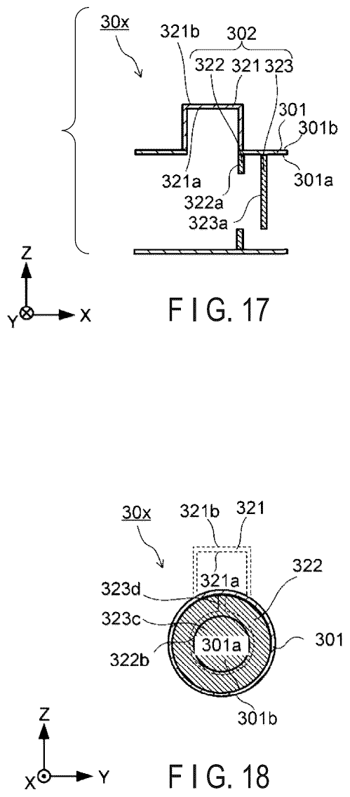

FIG. 17 and FIG. 18 are schematic diagrams illustrating a structure example of the pipe unit for forming the pipe 30 in the fifth embodiment. FIG. 17 schematically illustrates a cross-sectional structure example of the pipe unit 30x along the exhaust gas flow direction (the X axis direction for example). FIG. 18 schematically illustrates the structure example of the pipe unit 30x when viewed from the direction (the Z axis direction for example) perpendicular to the exhaust gas flow direction. Hereinafter, parts different from FIG. 4 and FIG. 5 will be described and the description of FIG. 4 and FIG. 5 can be appropriately referred to for the other parts.

The pipe unit 30x illustrated in FIG. 17 and FIG. 18 is different in that the trap 302 further includes a shielding body 323. The shielding body 323 may be joined with the inner peripheral surface 301a by welding.

The shielding surface 322a (e.g., first shielding surface) is, as illustrated in FIG. 18, an annular surface provided with the opening 322b. The annular surface extends inwardly from the edge of the recessed portion 321 into the pipe 301 along the Z axis direction for example.

The shielding body 323 has a second shielding surface 323a. The second shielding surface 323a includes, as illustrated in FIG. 18, a circular surface 323c and a beam surface 323d that connects the circular surface 323c and the inner peripheral surface 301a. The circular surface 323c overlaps a part or all of the opening 322b in the X axis direction of the pipe unit 30x for example. The circular surface 323c extends from the edge of the recessed portion 321 into the pipe 301 along the Z axis direction via the beam surface 323d for example. A width of the beam surface 323d may be smaller than a diameter of the circular surface 323c.

The fifth embodiment can be appropriately combined with the other embodiments. For example, similarly to the other embodiments, the pipe 30 can be formed by combining the plurality of pipe units 30x illustrated in FIG. 17 and FIG. 18.

### Sixth Embodiment

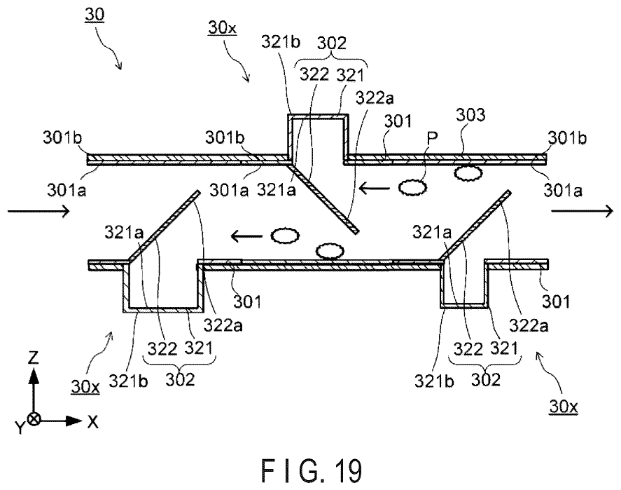

FIG. 19 is a schematic diagram illustrating a structure example of the pipe 30 in the sixth embodiment. FIG. 19 schematically illustrates a cross-sectional structure example of the pipe unit 30x along the exhaust gas flow direction (the X axis direction for example) indicated by arrows. Hereinafter, parts different from FIG. 6 will be described and the description of FIG. 6 can be appropriately referred to for the other parts.

The pipe 30 illustrated in FIG. 19 is different in that surface area of an inner surface 321a is larger as the plurality of recessed portions 321 are closer to (e.g., with increasing proximity to) the process chamber (the space 11a) in the X axis direction. In other words, the pipe 30 illustrated in FIG. 19 is different in that the surface area of the inner surface 321a is smaller as the plurality of recessed portions 321 are farther from or distal to the process chamber (the space 11a) in the X axis direction. The surface area of the inner surface 321a can be defined by a product of a length in the X axis direction and a length in the Z axis direction of the recessed portion 321.

In the pipe 30, a generation amount of the products P is likely to be larger as it is closer to the process chamber. Therefore, the backflow of the products P is effectively suppressed by increasing the surface area of the inner surface 321a of the recessed portion 321 closer to the process chamber, and the obstruction of the flow of the exhaust gas can be suppressed by reducing the surface area of the inner surface 321a of the recessed portion 321 farther from the process chamber.

The sixth embodiment can be appropriately combined with the other embodiments.

### Seventh Embodiment

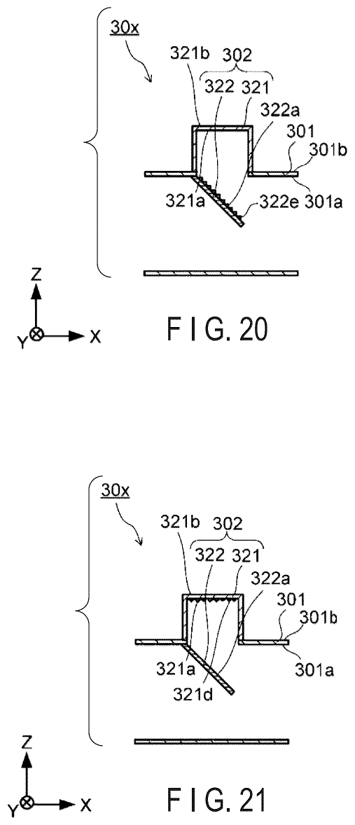

FIG. 20 is a schematic diagram illustrating a structure example of the pipe unit for forming the pipe 30 in the seventh embodiment. FIG. 20 schematically illustrates a cross-sectional structure example of the pipe unit 30x along the exhaust gas flow direction (the X axis direction for example). Hereinafter, parts different from FIG. 4 will be described and the description of FIG. 4 can be appropriately referred to for the other parts.

The pipe unit 30x illustrated in FIG. 20 is different in that it has a coarse surface 322e on the shielding surface 322a.

The coarse surface 322e is coarser or rougher than the inner peripheral surface 301a for example. By forming the coarse surface 322e, the surface area of the shielding surface 322a can be increased and the products P can be easily captured. Thus, the backflow of the products P can be suppressed.

The seventh embodiment can be appropriately combined with the other embodiments. For example, similarly to the other embodiments, the pipe 30 can be formed by combining the plurality of pipe units 30x illustrated in FIG. 20.

### Eighth Embodiment

FIG. 21 is a schematic diagram illustrating a structure example of the pipe unit for forming the pipe 30 in the eighth embodiment. FIG. 21 schematically illustrates a cross-sectional structure example of the pipe unit 30x along the exhaust gas flow direction (the X axis direction for example). Hereinafter, parts different from FIG. 4 will be described and the description of FIG. 4 can be appropriately referred to for the other parts.

The pipe unit 30x illustrated in FIG. 21 is different in that it has a coarse surface 321d on the inner surface 321a of the recessed portion 321.

The coarse surface 321d is coarser than the inner peripheral surface 301a for example. By forming the coarse surface 321d, the surface area of the inner surface 321a can be increased and the products P can be easily captured. Thus, the backflow of the products P can be suppressed. In addition, since the recessed portion 321 can be easily cooled, the products P can be easily captured.

The eighth embodiment can be appropriately combined with the other embodiments.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. The accompanying claims and their equivalents are intended to cover such forms or modification as would fall within the scope and spirit of the inventions.

What is claimed is

1. A semiconductor manufacturing device, comprising:
a pipe through which exhaust gas from a process chamber flows in a first direction; and
a plurality of traps on an inner peripheral surface of the pipe at intervals in the first direction, wherein
each of the plurality of traps includes
a recessed portion on the inner peripheral surface of the pipe and recessed outwardly from the inner peripheral surface, and
a shielding surface that extends inwardly from an edge of the recessed portion into the pipe along a second direction intersecting the first direction.

2. The semiconductor manufacturing device of claim 1, further comprising a heater surrounding an outer peripheral surface of the pipe,
wherein at least a part of an outer surface of the recessed portion is exposed by the heater.

3. The semiconductor manufacturing device of claim 1, wherein the recessed portions of the plurality of traps are recessed in directions different from each other when the pipe is viewed from the first direction.

4. The semiconductor manufacturing device of claim 1, wherein at least a part of an inner surface of the recessed portion or the shielding surface is coarser than the inner peripheral surface of the pipe.

5. The semiconductor manufacturing device of claim 1, wherein:
the shielding surface of one of the plurality of traps includes an opening therein, and
the shielding surface of another of the plurality of traps includes a surface that overlaps the opening in the shielding surface of the one of the plurality of traps in the first direction.

6. The semiconductor manufacturing device of claim 1, wherein:
one of the plurality of traps further includes a first shielding surface and a second shielding surface,
the first shielding surface includes an opening therein,
the second shielding surface is farther from the recessed portion than the first shielding surface,
the second shielding surface extends inwardly from the inner peripheral surface of the pipe into the pipe, and
the second shielding surface has a surface that overlaps the opening in the first shielding surface in the first direction.

7. The semiconductor manufacturing device of claim 1, wherein the shielding surface has a semicircular shape or a bow shape.

8. The semiconductor manufacturing device of claim 1, wherein surface areas of inner surfaces of the recessed portions of the plurality of traps increase with increasing proximity to the process chamber in the first direction.

9. The semiconductor manufacturing device of claim 1, wherein the recessed portions in at least two traps of the plurality of traps are recessed in directions different from each other when the pipe is viewed from the first direction.

10. The semiconductor manufacturing device of claim 1, wherein at least a part of an inner surface of the recessed portion is coarser than the inner peripheral surface of the pipe.

11. The semiconductor manufacturing device of claim 1, wherein at least a part of the shielding surface is coarser than the inner peripheral surface of the pipe.

12. The semiconductor manufacturing device of claim 1, wherein:
the shielding surface has the bow shape, and
a bowstring of the bow shape does not overlap a horizontal center axis of the pipe in the first direction.
